(19) United States
(12) Patent Application Publication
(10) Pub. No.: US 2026/0155350 A1
(43) Pub. Date: Jun. 4, 2026

(54) ANODE FOR SECONDARY BATTERY AND METHOD FOR MANUFACTURING THE SAME

(71) Applicant: KOREA INSTITUTE OF SCIENCE AND TECHNOLOGY, Seoul (KR)

(72) Inventors: Myoung-Woon MOON, Seoul (KR); Young A LEE, Seoul (KR); Sang Jin PARK, Seoul (KR); Gi Baek KIM, Seoul (KR); Min-Seok KIM, Seoul (KR); Eun Ji SEO, Seoul (KR); Chanyoung OH, Seoul (KR)

(21) Appl. No.: 19/343,999

(22) Filed: Sep. 29, 2025

(30) Foreign Application Priority Data
Dec. 3, 2024 (KR) 10-2024-0177231

(51) Int. Cl. H01M 4/133; H01J 37/317; H01M 4/02; H01M 4/04; H01M 4/134; H01M 4/1393; H01M 4/1395; H01M 4/36; H01M 4/38; H01M 4/587; H01M 4/62; H01M 4/66; H01M 10/42

(52) U.S. Cl. CPC H01M 4/133; H01M 4/0404; H01M 4/0426; H01M 4/134; H01M 4/1393; H01M 4/1395; H01M 4/366; H01M 4/38; H01M 4/587; H01M 4/625; H01M 4/626; H01M 4/628; H01M 4/661; H01M 10/4235; H01J 37/3171; H01M 2004/021; H01M 2004/027

(57) ABSTRACT

Provided is an anode for a secondary battery according to the inventive concept, wherein the anode includes an anode current collector, and a conductive nanostructure on the anode current collector, wherein the conductive nanostructure includes a core region including a core structure, and a first shell region including a metal pattern and a carbon pattern alternately stacked, and covering the core region.

### CROSS-REFERENCE TO RELATED APPLICATION

This U.S. non-provisional patent application claims priority under 35 U.S.C. § 119 of Korean Patent Application No. 10-2024-0177231, filed on Dec. 3, 2024, the entire contents of which are hereby incorporated by reference.

### BACKGROUND

The present disclosure herein relates to an anode for a secondary battery and a method for manufacturing the same, and more particularly, to an anode for a secondary battery using a conductive nanostructure and a method for manufacturing the same.

Compared to other energy storage devices such as a capacitor and a fuel cell, a secondary battery shows high storage capacity, low self-discharge, excellent charging-discharging characteristics, high processability, etc., and thus is attracting great attention as a next-generation eco-friendly energy storage device as its use is expanding not only to portable devices such as laptops and wearable devices, but also to mobile or large-scale storage devices such as electric vehicles, military equipment, and energy storage systems (ESS).

An alkali ion-series metal material such as lithium (Li), sodium (Na), or potassium (K) is used as a core material of the secondary battery. Particularly, lithium-based secondary batteries are commercialized and used in electric vehicles or portable electronic devices, and the demand thereof is rapidly increasing. The secondary battery has advantages of high energy density, high Coulombic efficiency, and low self-discharge characteristics. The secondary battery is a battery composed of a cathode, an anode, an electrolyte which provides a path for alkali ions to move between the cathode and the anode, and a polymer separator, and generates electrical energy by oxidation and reduction reactions when the alkali ions are inserted/extracted or intercalated/de-intercalated in the cathode and the anode.

An liquid electrolyte lithium secondary battery uses an oxide including lithium having high energy density as a cathode material, and uses a liquid electrolyte. Graphite, silicon, a graphite-silicon composite material, or lithium is mainly used as an anode material. However, there is a possibility that the lithium secondary battery may cause a battery explosion accident due to thermal runaway, and therefore, the safety issue is emerging as an important challenge. One of the main causes of the thermal runaway is reported to be the formation of lithium dendrites in an anode, and therefore, the control of the dendrites is considered a key factor in resolving the safety issue. On the anode surface of the secondary battery, graphite, which is the anode material, and copper (Cu) foil, which is a current collector which supports the anode material and collects charges have low affinity or wettability with respect to lithium ions and an electrolyte solution including the lithium ions. As a result, it is known that uneven charge and mass transfer at the interface easily leads to dendrite formation due to uneven precipitation of lithium ions. Various studies are being conducted to suppress the formation of lithium dendrites, such as modification of a liquid electrolyte, use of a solid electrolyte, or modification of an electrode (or current collector) which has high affinity and wettability with respect to lithium.

### SUMMARY

The present disclosure provides an anode for a secondary battery having high affinity with respect to alkali metal ions and improved electrical conductivity, and a method for manufacturing the same.

Objects to be achieved by the present invention are not limited to the object mentioned above, and other objects that are not mentioned above will be clearly understood by those skilled in the art from the following description.

An embodiment of the inventive concept provides an anode for a secondary battery including an anode current collector, and a conductive nanostructure on the anode current collector, wherein the conductive nanostructure includes a core region including a core structure, and a first shell region including alternately stacked metal patterns and carbon patterns, and covering the core region.

In an embodiment of the inventive concept, an anode for a secondary battery includes an anode current collector, a plurality of core regions extending on the anode current collector in a first direction perpendicular to the anode current collector, first shell regions covering each of the core regions, and including metal patterns and carbon patterns alternately stacked along the first direction, and second shell regions covering each of the first shell regions, and including a carbon liner, wherein each of the core regions includes a core structure and carbon particles.

In an embodiment of the inventive concept, a method for manufacturing an anode for a secondary battery includes stacking cellulose nanocrystals on an anode current collector to form a cellulose layer, and irradiating an ion beam onto the cellulose layer to form a core region, and while irradiating the ion beam, implanting metal ions onto the cellulose layer to form metal patterns and carbon patterns alternately repeated on the core region.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of a secondary battery according to embodiments of the inventive concept;

FIG. 2 is a view for describing an anode for a secondary battery according to an embodiment of the inventive concept, and is a cross-sectional view corresponding to region M1 of FIG. 1;

FIG. 3 is a cross-sectional photograph for describing an anode for a secondary battery according to an embodiment of the inventive concept;

FIG. 4 is a view for describing an anode for a secondary battery according to an embodiment of the inventive concept, and is a cross-sectional view corresponding to region M2 of FIG. 2;

FIG. 5 is a view for describing an anode for a secondary battery according to an embodiment of the inventive concept, and is a view observed through atomic probe tomography (APT);

FIG. 6 shows photographs for describing an anode for a secondary battery according to an embodiment of the inventive concept;

FIG. 7 shows experimental data for describing a composition of an anode for a secondary battery according to an embodiment of the inventive concept;

FIG. 8 is a photograph showing anodes for a secondary battery according to embodiments of the inventive concept;

FIG. 9 is a planar photograph for describing an anode for a secondary battery according to an embodiment of the inventive concept;

FIGS. 10, 11, and 12 are cross-sectional photographs for describing anodes for a secondary battery according to an embodiment of the inventive concept;

FIG. 13 is a photograph for showing a contact angle according to an embodiment of the inventive concept;

FIG. 14 is a photograph for showing a contact angle according to a comparative embodiment corresponding to the inventive concept;

FIG. 15 and FIG. 16 are experimental data respectively showing experimental results of an embodiment and a comparative embodiment of the inventive concept;

FIG. 17 and FIG. 18 are experimental data showing charging-discharging evaluation values of a half-cell to which an anode according to an embodiment of the inventive concept is applied;

FIG. 19 shows experimental data showing an area capacity of a half-cell to which an anode according to an embodiment of the inventive concept is applied;

FIG. 20 shows experimental data showing a charging-discharging cycle and a specific capacity of a secondary battery to which an anode according to an embodiment of the inventive concept is applied;

FIG. 21 shows experimental data showing values of charging-discharging capacity measured according to cycles of a secondary battery to which an anode according to an embodiment of the inventive concept is applied;

FIG. 22 shows experimental data showing values of Coulombic efficiency measured according to cycles of a secondary battery to which an anode according to an embodiment of the inventive concept is applied;

FIG. 23 and FIG. 24 are views for describing a method for manufacturing an anode for a secondary battery according to an embodiment of the inventive concept;

FIGS. 25, 26, 27, 28, 29, 30, 31, 32, 33, 34, 35, and 36 are photographs showing a process of manufacturing an anode for a secondary battery according to an embodiment of the inventive concept; and

FIG. 37 shows experimental data showing sheet resistance of each of embodiments and comparative embodiments of the inventive concept.

### DETAILED DESCRIPTION

In order to facilitate sufficient understanding of the configuration and effects of the inventive concept, preferred embodiments of the inventive concept will be described with reference to the accompanying drawings. However, the inventive concept is not limited to the embodiments set forth below, and may be embodied in various forms and modified in many alternate forms. Rather, these embodiments are provided such that the disclosure of the inventive concept will be thorough and complete, and will fully convey the scope of the inventive concept to those skilled in the art to which the inventive concept pertains. In the accompanying drawings, elements are illustrated enlarged from the actual size thereof for convenience of description, and the ratio of each element may be exaggerated or reduced.

The terms used herein are for the purpose of describing embodiments and are not intended to be limiting of the inventive concept. In the present specification, singular forms include plural forms unless the context clearly indicates otherwise. As used herein, the terms “comprises” and/or “comprising” are intended to be inclusive of the stated elements, steps, operations and/or devices, and do not exclude the possibility of the presence or the addition of one or more other elements, steps, operations, and/or devices.

In the present specification, when any film (or layer) is referred to as being on another film (or layer) or substrate, it means that the film may be directly formed on another film(or layer) or substrate, or that a third film(or layer) may be interposed therebetween.

In addition, embodiments described in the present specification will be described with reference to cross-sectional views and/or plan views which are ideal illustrations of the inventive concept. In the drawings, the thickness of films and regions are exaggerated for an effective description of technical contents. Accordingly, the shape of an exemplary drawing may be modified by manufacturing techniques and/or tolerances. Thus, the embodiments of the inventive concept are not limited to specific forms illustrated, but are intended to include changes in the form generated by a manufacturing process. Thus, the regions illustrated in the drawings have schematic properties, and the shapes of the regions illustrated in the drawings are intended to exemplify specific shapes of regions of a device and are not intended to limit the scope of the inventive concept.

Unless otherwise defined, terms used in the embodiments of the inventive concept may be interpreted as meanings commonly known to those skilled in the art.

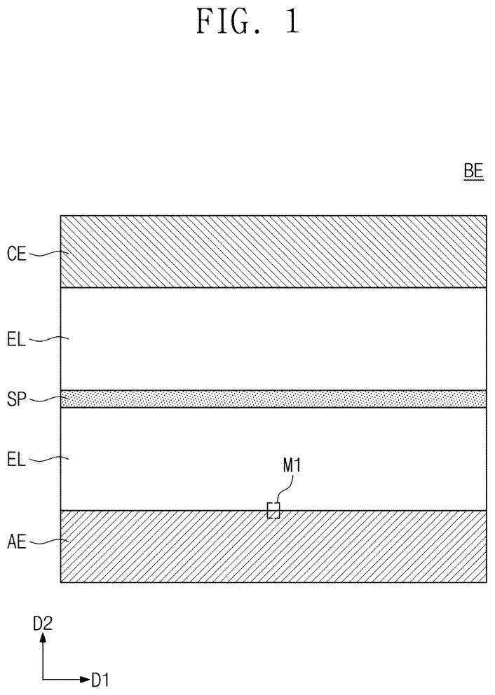

FIG. 1 is a cross-sectional view of a secondary battery according to embodiments of the inventive concept.

Referring to FIG. 1, a secondary battery BE may include a cathode CE, an anode AE, a separator SP, and an electrolyte EL. The cathode CE and the anode AE may be disposed spaced apart from each other, and may oppose each other. The separator SP may be interposed between the cathode CE and the anode AE, and the electrolyte EL may fill a space between the cathode CE and the separator SP and between the anode AE and the separator SP. The anode AE will be described later.

As an example, the secondary battery BE may be a secondary battery (e.g., a lithium secondary battery) including an alkali metal. As an example, the secondary battery BE may be classified into a cylindrical type, a pouch type, a coin type, and the like depending on the type thereof.

The cathode CE may include a cathode current collector and a cathode active material. As an example, the cathode active material may include at least one of sulfur, LiCoO₂, LiNiO₂, LiNixCoyMnzO₂ (x+y+z=1), LiMn₂O₄, and LiFePO₄, but is not limited to. As an example, the cathode current collector may include at least one of aluminum (Al), titanium (Ti), copper (Cu), iron (Fe), or a combination thereof, but is not limited thereto.

The separator SP may serve to prevent a short circuit between the anode AE and the cathode CE, and ions (e.g., lithium ions) in the electrolyte EL may pass through the separator SP and move to the cathode CE and the anode AE. However, the separator SP may be omitted depending on the type of the secondary battery BE. As an example, the separator SP may use polyethylene, polypropylene, polyvinylidene fluoride, or a multilayer of two or more layers thereof, but is not limited thereto.

The electrolyte EL may serve to prevent a short circuit between the cathode CE and the anode AE, and may serve to transfer ions (e.g., lithium ions) to the cathode CE and the anode AE. The electrolyte may include a non-aqueous organic solvent and an alkali salt (e.g., a lithium salt).

The non-aqueous organic solvent may include an alcohol-based solvent, but is not limited thereto. As an example, the non-aqueous organic solvent may include at least one of ethylene carbonate, dimethyl carbonate, ethyl methyl carbonate, or a combination thereof, but is not limited thereto.

The alkali salt may be dissolved in the non-aqueous organic solvent, thereby serving to accelerate the movement of ions (e.g., lithium ions) between the cathode and the anode. As an example, the lithium salt of the alkali salt may include at least one of LiPF₆, LiBF₄, LiSbF₆, LiAsF₆, LiClO₄, LiAlO₂, LiAlCl₄, LiPO₂F₂, LiCl, LiI, or a combination thereof.

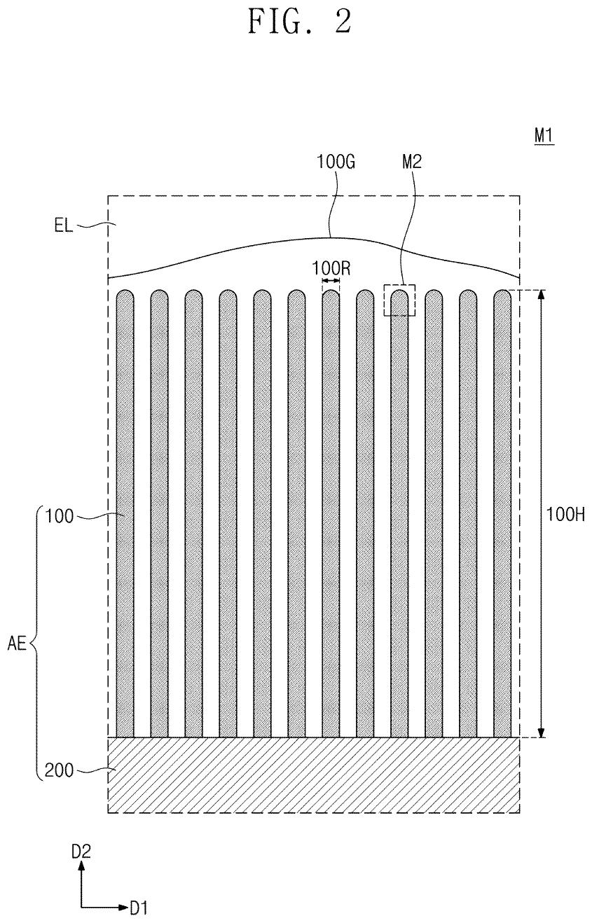

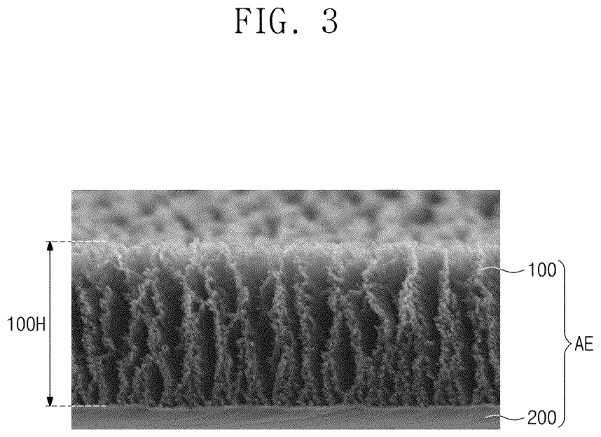

FIG. 2 is a view for describing an anode for a secondary battery according to an embodiment of the inventive concept, and is a cross-sectional view corresponding to region M1 of FIG. 1. FIG. 3 is a cross-sectional photograph for describing an anode for a secondary battery according to an embodiment of the inventive concept.

Referring to FIG. 2 and FIG. 3, the anode AE may include an anode current collector 200 and a conductive nanostructure group 100G on the anode current collector 200.

As an example, the anode current collector 200 may include at least one of aluminum (Al), titanium (Ti), copper (Cu), iron (Fe), or a combination thereof, but is not limited thereto.

The conductive nanostructure group 100G may include a plurality of conductive nanostructures 100. On the anode current collector 200, the conductive nanostructures 100 may be disposed along a first direction D1, and may extend in a second direction D2. In the present specification, the second direction D2 may refer to a direction perpendicular to an upper surface of the anode current collector 200, and the first direction D1 may refer to a direction parallel to the upper surface of the anode current collector 200 and perpendicular to the second direction D2. As another example, unlike the above description, the conductive nanostructures 100 may extend at an acute angle with respect to the upper surface of the anode current collector 200.

The conductive nanostructure 100 may have a shape of at least one of a nanowire, a nanotube, or a nanopyramid. The conductive nanostructure 100 may include one edge and the other edge. One edge of each of the conductive nanostructures 100 may be independently separated from each other. The other edge of each of the conductive nanostructures 100 may be connected to the anode current collector 200. During a process of forming the conductive nanostructure 100, a portion of the anode current collector 200 around the conductive nanostructure 100 may melt, so that the conductive nanostructure 100 may be bonded to the anode current collector 200. In other words, the conductive nanostructure 100 may be bonded to the upper surface of the anode electrode current collector 200, thereby having a shape of protruding in the second direction D2.

The electrolyte EL which fills a space between each of the conductive nanostructures 100 may be provided. In other words, the electrolyte EL may surround each of the conductive nanostructures 100, and may come in contact with the upper surface of the anode current collector 200.

The conductive nanostructure 100 may have a diameter 100R of approximately 1 nm to approximately 3 μm. The diameter 100R may be defined as a width of the conductive nanostructure 100 bonded to the anode current collector 200 in the first direction D1.

The conductive nanostructure 100 may have a first height 100H of approximately 10 nm to approximately 50 μm. The first height 100H may be defined as a length in the second direction D2 from the upper surface of the anode current collector 200 to the uppermost surface of the conductive nanostructure 100.

An aspect ratio obtained by dividing the first height 100H of the conductive nanostructure 100 by the diameter 100R thereof may be approximately 0.0033 to approximately 10,000, and preferably approximately 0.4 to approximately 700. For example, if in a shape of conductive nanotubes, the conductive nanostructure 100 may have a first height 100H of approximately 500 nm or less, and a wall forming the nanotubes may have a thickness of approximately 10 nm to approximately 15 nm.

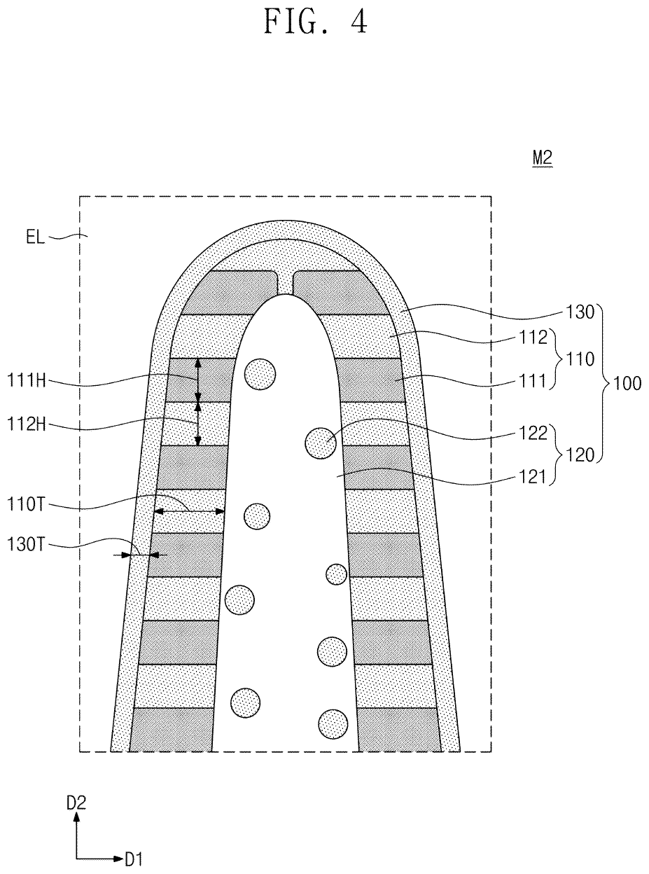

FIG. 4 is a view for describing an anode for a secondary battery according to an embodiment of the inventive concept, and is a cross-sectional view corresponding to region M2 of FIG. 2.

Referring to FIG. 4, the conductive nanostructure 100 may include a core region 120, a first shell region 110, and a second shell region 130.

The core region 120 may be connected to the anode current collector 200. The core region 120 may include a core structure 121 and carbon particles 122. The core region 120 may extend in the second direction D2 from the upper surface of the anode current collector 200. As an example, the core region 120 may have a shape of at least one of a nanowire, a nanotube, or a nanopyramid.

The core structure 121 may include a cellulose material. As an example, the cellulose material may include at least one of cellulose nanoparticles, cellulose nanocrystals, cellulose nanofibers, or a combination thereof. The core structure 121 may be a matrix formed of the cellulose material. The matrix structure of the core structure 121 may be formed by irradiating stacked cellulose materials with an ion beam.

The carbon particles 122 may be present inside the core structure 121. The carbon particles 122 may be dispersed in the core structure 121 and provided in plurality. The carbon particles 122 may be formed by the core structure 121 which is partially carbonized in an ion implantation process to be described later.

The core structure 121 may include a carbonyl group (C═O). The carbonyl group may be formed by the core structure 121 which is partially carbonized and reacts with an oxygen in the core structure 121 in the ion implantation process to be described later. The carbonyl group may improve wettability of the electrolyte EL, and the core structure 121 including the carbonyl group, and the conductive nanostructure 100 may have high wettability with respect to the electrolyte EL. As a result, the anode for a secondary battery including the conductive nanostructure 100 may have improved electrical conductivity.

The first shell region 110 may be provided covering the core region 120. The first shell region 110 may include metal patterns 111 and carbon patterns 112 which are alternately stacked along the second direction D2. Each of the metal patterns 111 may have a second height 111H in the second direction D2, and each of the carbon patterns 112 may have a third height 112H in the second direction D2. The second height 111H and the third height 112H may be the same as or different from each other. As an example, the second height 111H may be approximately 3 nm to approximately 50 nm, and the third height 112H may be approximately 3 nm to approximately 20 nm, but as to be described below, the second and third heights 111H and 112H may be controlled by adjusting the type, energy, and irradiation time of the ion beam.

As an example, the metal pattern 111 may include at least one of silicon (Si), graphene, graphite, iron (Fe), gold (Au), silver (Ag), platinum (Pt), palladium (Pd), iridium (Ir), ruthenium (Ru), titanium (Ti), nickel (Ni), copper (Cu), zinc (Zn), tin (Sn), magnesium (Mg), aluminum (Al), or a combination thereof.

As an example, the carbon pattern 112 may include at least one of carbon (C), carbon monoxide (CO), hard carbon, soft carbon, or a combination thereof.

Although not illustrated, oxygen particles (not shown) may be additionally disposed inside the first shell region 110. The oxygen particles (not shown) may be disposed between the metal pattern 111 and the carbon pattern 112.

The second shell region 130 may cover the first shell region 110. The second shell region 130 may be spaced apart from the core region 120 with the first shell region 110 interposed therebetween. A thickness 130T of the second shell region 130 may be smaller than a thickness 110T of the first shell region 110. The thickness 110T of the first shell region 110 may be defined as a length in the first direction D1 from an outer surface of the core region 120 to an outer surface of the first shell region 110. The thickness 130T of the second shell region 130 may be defined as a length in the first direction D1 from an outer surface of the first shell region 110 to an outer surface of the second shell region 130. The second shell region 130 may have a line shape from a cross-sectional viewpoint. As an example, the second shell region 130 may be a carbon liner formed of carbon. The second shell region 130 may be electrically connected to the metal pattern 111 and the carbon pattern 112 adjacent to each other in the first shell region 110.

The conductive nanostructure 100 includes the metal patterns 111, carbon (C), and the carbonyl groups, and thus, may serve to store and emit alkali ions. In other words, the conductive nanostructure 100 may serve as an anode active material.

The conductive nanostructure 100 includes carbonyl groups, and thus may have a lithiophilic surface with respect to the alkali ions, thereby suppressing formation of dendrites, and therefore, an anode for a secondary battery including the conductive nanostructure 100 may be electrochemically stable compared to an anode for a secondary battery not including the conductive nanostructure 100.

The conductive nanostructure 100 has a structure protruding in the second direction D2, so that the contact area between the electrolyte EL and the anode AE may increase, and therefore, the alkali ions may be more easily intercalated and deintercalated during charging-discharging.

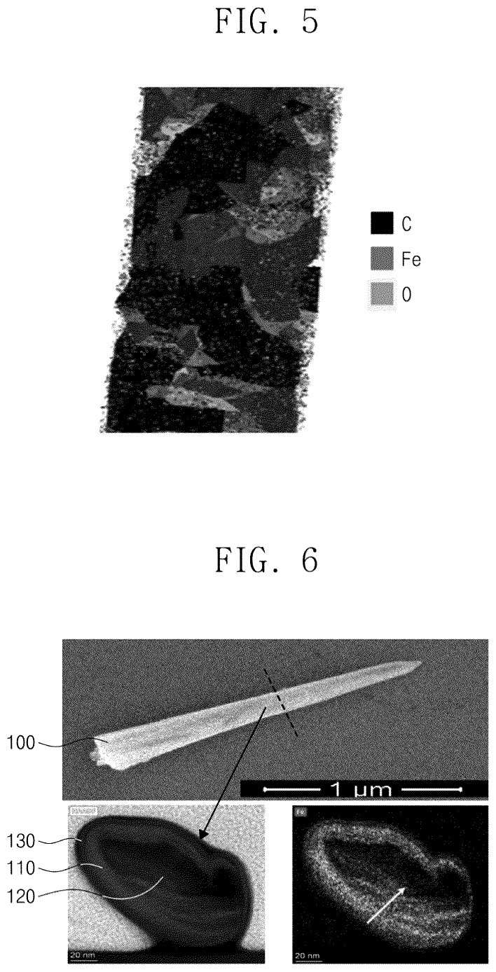

FIG. 5 is a view for describing an anode for a secondary battery according to an embodiment of the inventive concept, and is a view observed through atomic probe tomography (APT).

Referring to FIG. 5, it can observed that iron (Fe) representing a metal pattern 111 and carbon (C) representing a carbon pattern 112 are alternately disposed in a conductive nanostructure 100.

FIG. 6 shows photographs for describing an anode for a secondary battery according to an embodiment of the inventive concept. More specifically, the photographs of FIG. 6 are, from the top left in order, a photograph of a conductive nanostructure formed on the anode for a secondary battery, a TEM photograph obtained by observing a cross-section according to a yellow dotted line of the above-described photograph, and a transmission electron microscope-energy dispersive X-ray spectroscopy (TEM-EDS) photograph.

Referring to FIG. 6, in a conductive nanostructure 100, carbon (C) in first and second shell regions 110 and 130 may be observed, and iron (Fe) in the first shell region 110 may be observed. It can be confirmed that the carbon (C) is distributed more in the second shell region 130 than in the first shell region 110, and it can be confirmed that the iron (Fe) is not observed in the core region 120.

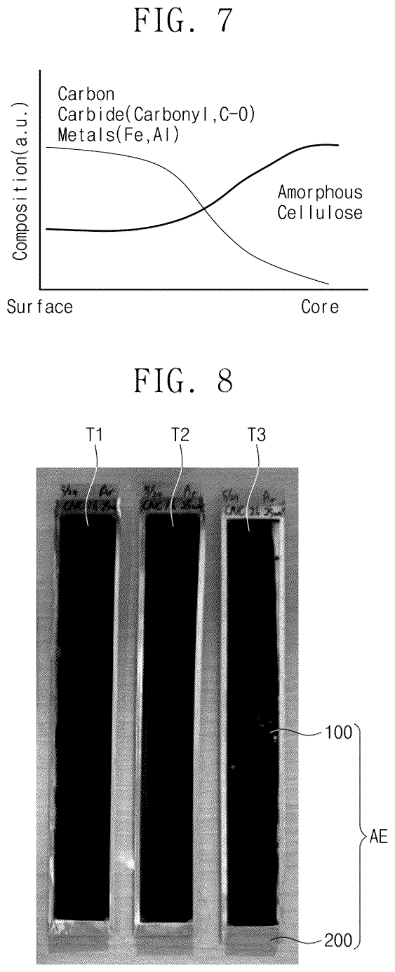

FIG. 7 shows experimental data for describing a composition of an anode for a secondary battery according to an embodiment of the inventive concept. More specifically, the experimental data of FIG. 7 is a graph showing changes in the chemical amount of each of carbon (C), a metal, and carbonyl (CO) when the measurement position changes from the surface of a conductive nanostructure to the core thereof.

Referring to FIG. 7, it can be confirmed that the composition ratio of cellulose increases from the surface (e.g., the first and second shell regions) of a conductive nanostructure 100 toward the core region 120, and on the contrary, it can be confirmed that the composition ratio of iron (Fe) and a carbonyl group decreases.

FIG. 8 is a photograph showing anodes for a secondary battery according to embodiments of the inventive concept.

Referring to FIG. 8, first, second, and third test anodes T1, T2, and T3 are embodiments manufactured according to the inventive concept. The first and second test anodes T1 and T2 are manufactured by performing an argon (Ar) ion beam process and a metal ion implantation process on cellulose nanocrystals on a copper (Cu) thin film for 1 hour, and the third test anode T3 is manufactured by performing an argon (Ar) ion beam process and a metal ion implantation process on cellulose nanocrystals on a copper (Cu) thin film for 2 hours.

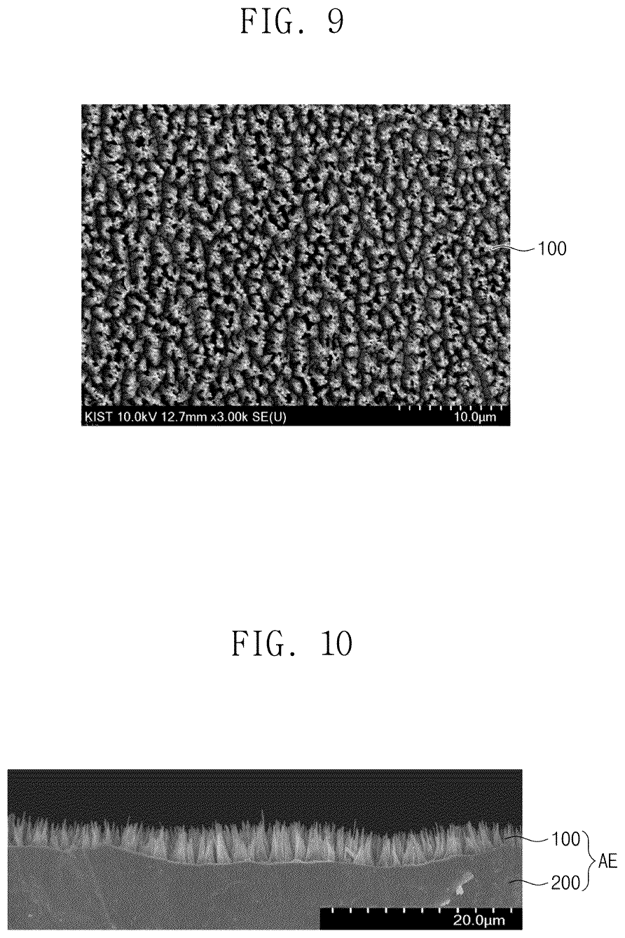

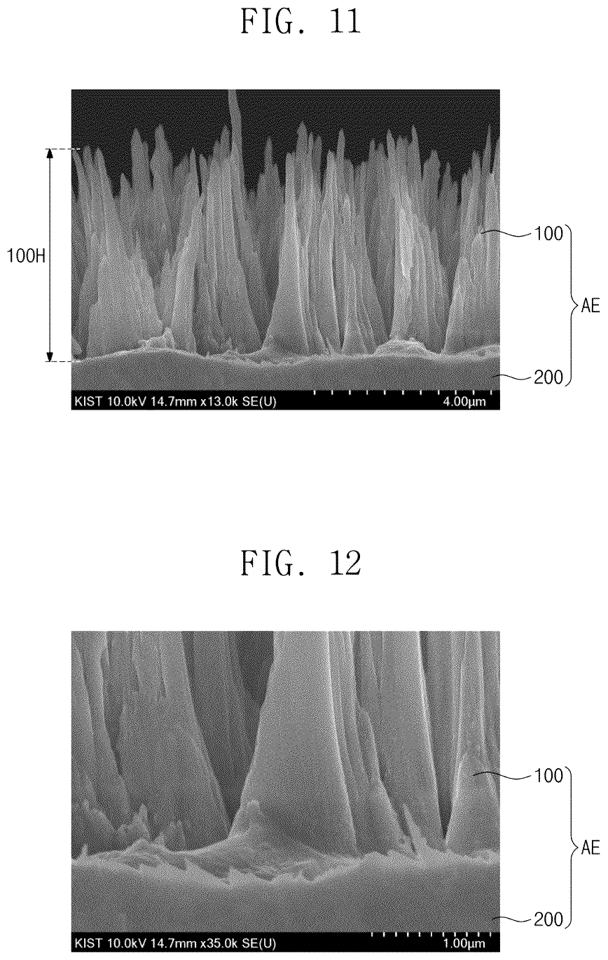

FIG. 9 is a planar photograph for describing an anode for a secondary battery according to an embodiment of the inventive concept. FIG. 10 to FIG. 12 are cross-sectional photographs for describing anodes for a secondary battery according to an embodiment of the inventive concept. Specifically, FIG. 9 to FIG. 12 are SEM photographs of the second test anode T2.

Referring to FIG. 9 to FIG. 11, it can be observed that the conductive nanostructure group 100G (100G of FIG. 2) includes a plurality of conductive nanostructures 100 spaced apart from each other, and it can be observed that each conductive nanostructure has a structure of extending in a direction perpendicular to an upper surface of an anode current collector 200 on the anode current collector 200.

Referring to FIG. 12, it can be observed that the conductive nanostructure 100 and the anode current collector 200 are firmly bonded after the ion beam process and the ion implantation process are performed.

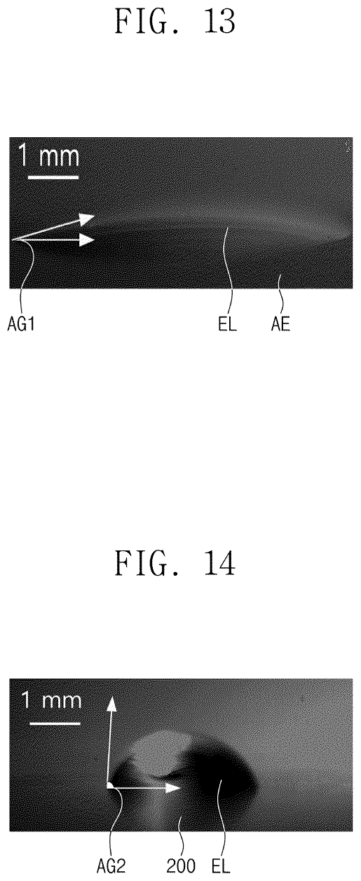

FIG. 13 is a photograph for showing a contact angle according to an embodiment of the inventive concept. More specifically, the photograph of FIG. 13 is a photograph showing a contact angle of an electrolyte measured on an anode.

As an anode AE of the present embodiment, the second test anode (T2 of FIG. 8) was used, and as an electrolyte EL, LiPF₆-EC: DMC was used. Referring to FIG. 13, it can be observed that the electrolyte EL is evenly spread on the anode AE. That is, it can be observed that the anode AE has a small first contact angle AG1 with respect to the electrolyte EL and has high wettability.

FIG. 14 is a photograph for showing a contact angle according to a comparative embodiment corresponding to the inventive concept. More specifically, the photograph of FIG. 14 is a photograph showing a contact angle of an electrolyte measured on an anode current collector.

As an anode current collector 200 of the comparative embodiment, copper (Cu) foil was used, and as an electrolyte EL, LiPF₆-EC: DMC was used. Referring to FIG. 14, it can be observed that the electrolyte EL is not evenly spread on the anode current collector 200. That is, it can be observed that the surface of the copper, which is the anode current collector 200, has a large second contact angle AG2 with respect to the electrolyte EL and has low wettability.

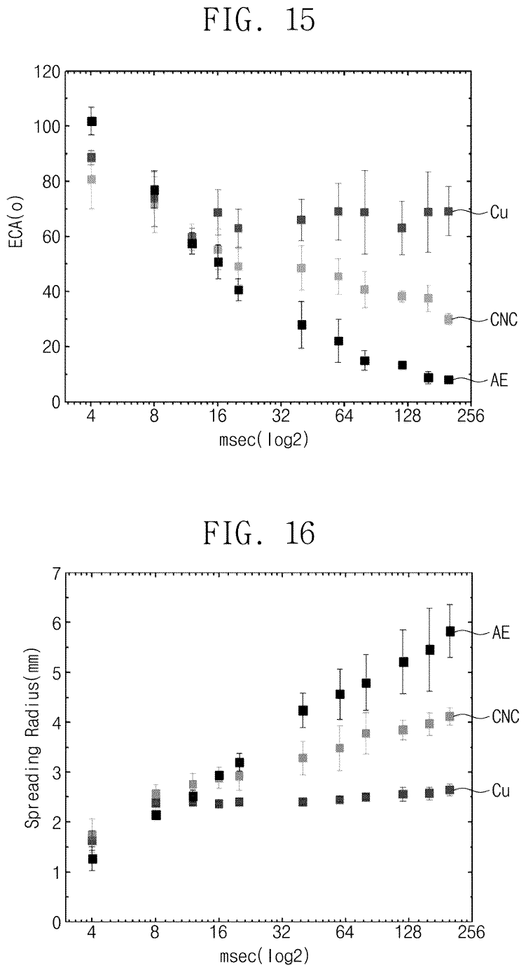

FIG. 15 and FIG. 16 are experimental data respectively showing experimental results of an embodiment and a comparative embodiment of the inventive concept. More specifically, FIG. 15 and FIG. 16 are respectively experimental data corresponding to the contact angle photographs of FIG. 13 and FIG. 14. FIG. 15 shows experimental data showing a contact angle of an electrolyte measured on each of copper (Cu) foil, cellulose nanocrystals before ion beam treatment, and an anode after the ion beam treatment. FIG. 16 shows experimental data showing a spreading radius of the electrolyte measured on each of the copper (Cu) foil, the cellulose nanocrystals before the ion beam treatment, and the anode after the ion beam treatment.

In the experimental data presented through FIG. 15 and FIG. 16, the second test anode T2 of FIG. 8 was used as an anode AE used in Example, only copper (Cu) foil was used as an anode AE used in Comparative Example 1 corresponding thereto, and an electrode in which only copper (Cu) foil and a cellulose layer (CNC) on the copper (Cu) foil were deposited was used as an anode AE used in Comparative Example 2. The second test anode T2 may include copper (Cu) foil and a conductive nanostructure 100 on the copper (Cu) foil. As an electrolyte EL, LiPF₆-EC: DMC was used.

Referring to FIG. 15, it can be observed that in all Experimental Example, Comparative Example 1, and Comparative Example 2, the contact angle decreases as the time of contact with the electrolyte EL increases, but it can be observed that in Experimental Example, the contact angle decreases more than in Comparative Example 1 and Comparative Example 2. As a result, it can be seen that the anode (AE) used in Experimental Example has higher wettability with respect to the electrolyte EL than those used in Comparative Example 1 and Comparative Example 2.

Referring to FIG. 16, it can be observed that in all Experimental Example, Comparative Example 1, and Comparative Example 2, the diameter of drops of the electrolyte EL increases as the time of contact with the electrolyte EL increases, but it can be observed that in Experimental Example, the diameter thereof increases more rapidly and more continuously than in Comparative Example 1 and Comparative Example 2. As a result, it can be seen that the anode (AE) used in Experimental Example has higher wettability than Comparative Example 1 and Comparative Example 2, and has uniform wettability.

Accordingly, the anode (AE) of Experimental Example, that is, an anode for a secondary battery including the conductive nanostructure 100, has uniform and large wettability with respect to the electrolyte EL, and thus, may suppress the formation of dendrites, thereby improving lifespan characteristics of the anode for a secondary battery.

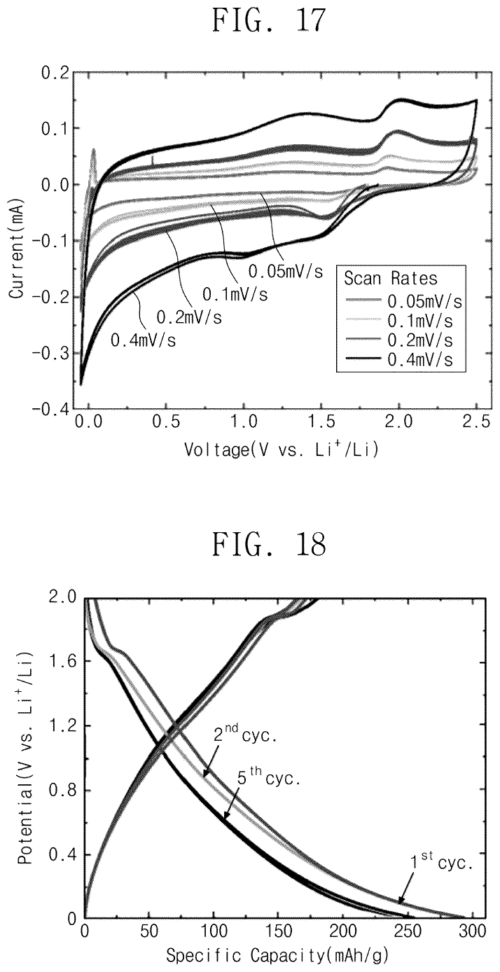

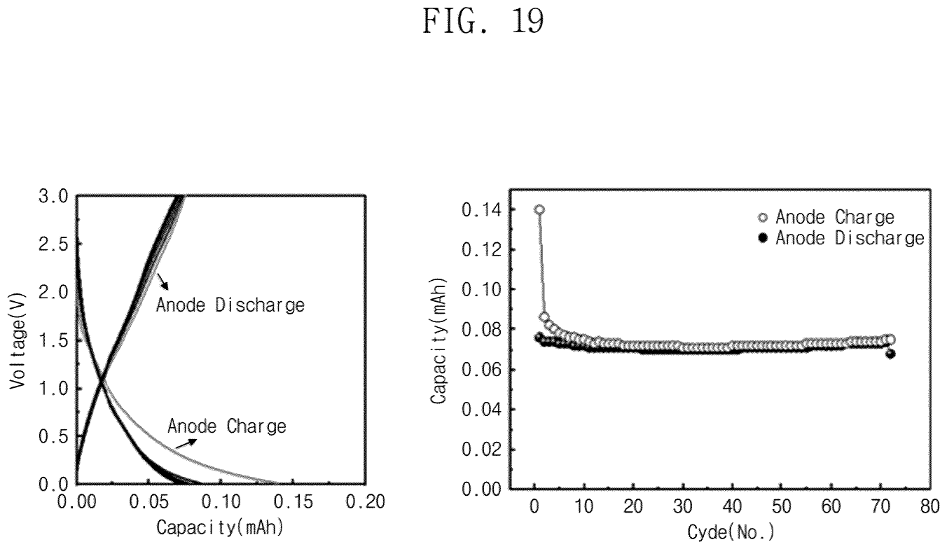

FIG. 17 and FIG. 18 are experimental data showing charging-discharging evaluation values of a half-cell to which an anode according to an embodiment of the inventive concept is applied. FIG. 19 shows experimental data showing an area capacity of a half-cell to which an anode according to an embodiment of the inventive concept is applied.

In FIG. 17 to FIG. 19, in order to perform electrochemical analysis on an anode for a secondary battery, the anode for a secondary battery including the conductive nanostructure 100 according to an embodiment of the inventive concept was applied to manufacture a half cell and a full cell, and electrochemical characteristics of the half-cell and the full-cell were measured.

In the half-cell configuration, copper foil including a material having the conductive nanostructure 100 was used as a working electrode, lithium metal foil was used as a reference electrode, and 1 M of LiPF₆ in EC/DMC/DEC having a volume ratio (1:1) was used as an electrolyte solution. Polypropylene (PP) was used as a separator. In addition, the half cell is composed of CAP(SUS304), CAN(SUS304), a gasket, and a spacer.

The secondary battery half cell is a 2032 coin-type battery, and was assembled in an argon (Ar) atmosphere glove box (glove-box, CHLAB T2, Choa ENG Co.) while maintaining the concentration of oxygen and moisture below approximately 1 ppm.

The evaluation and measurement of electrochemical performance were performed using a charging-discharging measurement device (cycler, WBCS3000S, Wonatech Co.) in a thermostat at 25° C. After 24 hours of rest to allow the electrolyte solution to completely wet the inside of the half-cell, the measurement of cyclic voltammetry (CV) and the evaluation of galvanostatic charging-discharging (GCD) were performed. The measurement of cyclic voltammetry was performed in a range of 0 V to 2.0 V under the scan rate conditions of 0.05 mV/sec, 0.1 mV/sec, and 0.2 mV/sec, and the evaluation of charging-discharging was performed in a charging-discharging range of 0 V to 2.0 V, which was the measurement voltage range, at a low rate of 0.2 C.

Referring to FIG. 17, it is possible to confirm results of the cyclic voltammetry measurement experiment performed to confirm an electrochemical reaction on the surface of the anode AE in which the conductive nanostructure 100 is formed. These are results of experiments conducted on the half cell at scan rates of 0.05 mV/s, 0.1 mV/s, and 0.2 mV/s for 5 cycles, respectively.

An anode reduction peak appearing in the first cycle between 0.6 V and 1.0 V indicates the formation of a solid electrolyte interface formed on the surface of the anode, and does not appear after the second cycle.

A reduction peak due to lithium ion insertion is formed around 0.05 V to 0.1 V, and this is a potential peak consistently reproduced over several cycles, from which it can be confirmed that there is a potential similar to a lithium insertion potential of a half cell of graphite or carbon-based series.

In addition, a reduction peak appears at approximately 1.5 V to 1.7 V, and this indicates a reversible reaction potential due to a reaction between lithium and the surface of a metal oxide.

A cathode oxidation peak appears around approximately 0.1 V to 0.2 V due to deintercalation of lithium, and a peak also appears within 1.8 V to 2.0 V due to deintercalation of lithium on the surface of an oxide layer. In addition, as the scan rate increases, the cyclic voltammetry graph becomes thicker overall, and this is presumed to be because a behavior in which lithium is absorbed on the surface of a material, thereby causing lithium (Li) plating is dominant over an intercalation behavior in which lithium enters the material, so that pseudo-capacitance characteristics are exhibited.

Referring to FIG. 18, it is possible to confirm a specific capacitance graph according to the charging-discharging evaluation performed on the half cell including the anode AE in which the conductive nanostructure 100 is formed.

It can be seen that the charging-discharging capacity of the half cell including the anode AE in which the conductive nanostructure 100 was formed showed a high initial capacity of 292.8 mAh/g at a c-rate (charging-discharging rate based on battery capacity) of 0.16 C, and was reduced to 250 mAh/g in the second cycle. Thereafter, it can be seen that the charging-discharging capacity was stably maintained at 240 mAh/g even at the 50-th cycle. Particularly, as shown in the cyclic voltammetry graph (FIG. 17), it can be seen that a lithium deintercalation phenomenon caused by a metal oxide layer occurred in a range of 1.6 V to 1.65 V, and a low deintercalation phenomenon occurred in a range of lower than 0.5 V.

Referring to FIG. 19, the left graph in FIG. 19 represents an areal capacity, which was measured at 0.131 mAh/cm² in the first cycle, and gradually decreased to 0.09 mAh/cm² to 0.075 mAh/cm² from the second to the 50-th cycles. According to the right graph in FIG. 19, it can be seen that Coulombic efficiency (CE) indicating the ratio of charging-discharge capacity according to cycles is maintained at 90% or greater except for the first cycle.

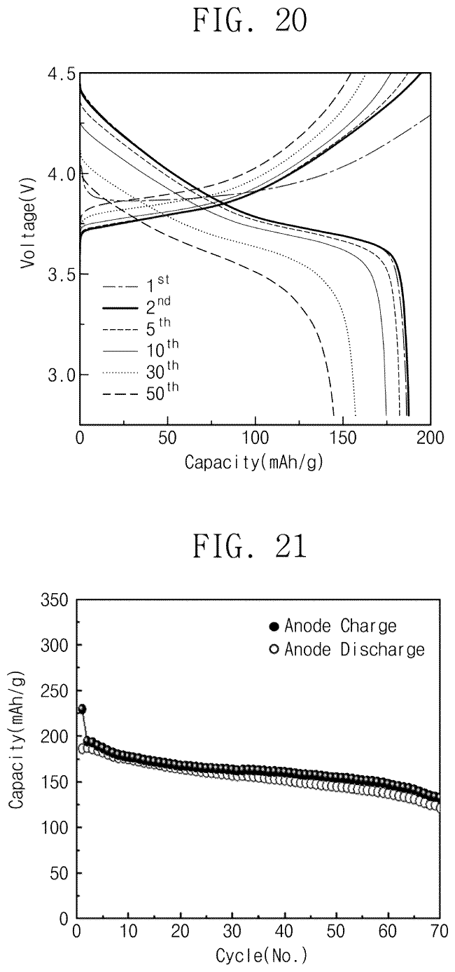

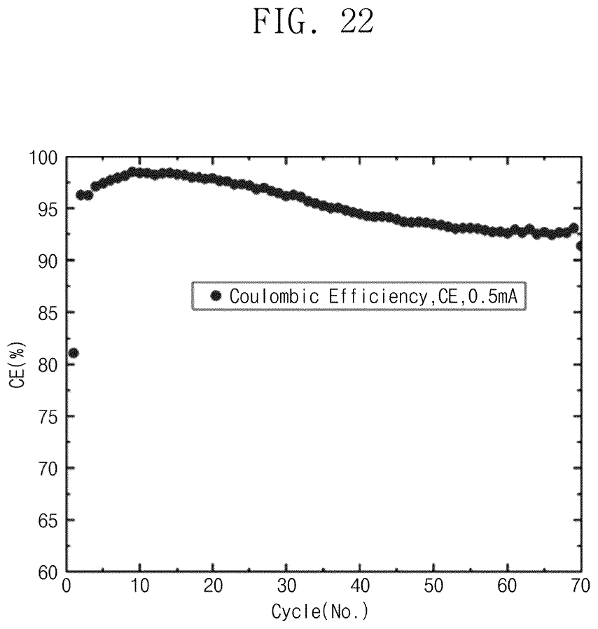

FIG. 20 shows experimental data showing a charging-discharging cycle and a specific capacity of a secondary battery to which an anode according to an embodiment of the inventive concept is applied. FIG. 21 shows experimental data showing values of charging-discharging capacity measured according to cycles of a secondary battery to which an anode according to an embodiment of the inventive concept is applied. FIG. 22 shows experimental data showing values of Coulombic efficiency measured according to cycles of a secondary battery to which an anode according to an embodiment of the inventive concept is applied.

In FIG. 20 to FIG. 22, the evaluation of electrochemical performance was performed on a secondary battery full cell by applying the anode for a secondary battery including the conductive nanostructure 100 according to an embodiment of the inventive concept. The full cell was manufactured using a 2032 coin-type battery, and was manufactured in an argon (Ar) atmosphere glove box. The manufacturing was performed while maintaining the concentration of oxygen and moisture below approximately 1 ppm. The full cell included an anode AE including copper foil in which the conductive nanostructure 100 was formed, used NCM532 as a cathode in the full cell, and used 1 M of LiPF₆ in EC/DMC/DEC having a volume ratio (1:1) as an electrolyte solution. Polypropylene was used as a separator.

The evaluation and measurement of the performance were performed using a charging-discharging measurement device in a thermostat at 25° C., and after 24 hours of rest to allow the electrolyte solution to completely wet the inside of the full cell, the evaluation of galvanostatic charging-discharging was performed. The measurement conditions were a low rate of 0.2 C and a charging-discharging range of 3 V to 4.5 V.

The anode AE was copper foil having the conductive nanostructure 100 in which cellulose had conductivity by argon ion beam treatment, and the ion beam treatment was performed by vertical irradiation on the surface of a sample for 1 hour to produce the conductive nanostructure 100.

Referring to FIG. 20, a specific capacity in the first cycle was 183 mAh/g when the polypropylene separator was used, from which it can be seen that the specific capacity was similar due to the same cathode material. An irreversible capacity exhibited in the first charge was almost similar to that of the cathode active material, and the cycle stability was better after the second cycle. The irreversible capacity is a capacity which is not reversibly used but is lost, and may refer to a difference between a charge capacity and a discharge capacity in a specific cycle. That is, a remainder obtained by subtracting the irreversible capacity from the charge capacity may be referred to as a reversible capacity, and the reversible capacity may be referred to as the discharge capacity.

Referring to FIG. 21, values of specific capacity measured according to charging-discharging cycles during charging-discharging are shown. It can be seen that the charge capacity gradually decreases except for the first cycle.

Referring to FIG. 22, high and uniform charging-discharging efficiency of 90% or higher was measured up to the 70-th cycle. The charging-discharging efficiency may refer to the ratio of charges used in a reduction reaction of the cathode/an oxidation reaction of the anode during discharge.

The experimental data described with reference to FIG. 17 to FIG. 22 are merely experimental data according to an embodiment of the inventive concept, and specific numerical values or ratios may vary depending on the configuration of a battery.

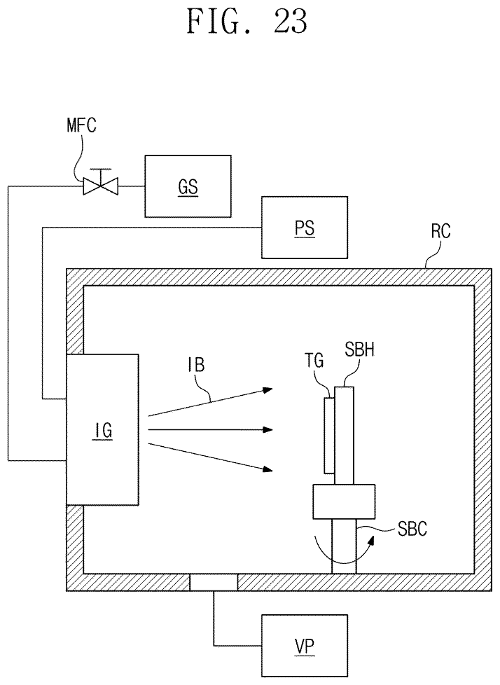

FIG. 23 and FIG. 24 are views for describing a method for manufacturing an anode for a secondary battery according to an embodiment of the inventive concept. Specifically, FIG. 23 is a schematic view of an apparatus for manufacturing an anode for a secondary battery, and FIG. 24 is a cross-sectional view when a conductive nanostructure is irradiated with an ion beam.

Referring to FIG. 23, a substrate processing apparatus may be provided. The substrate processing apparatus may be an apparatus which performs processing on an anode current collector 200 by using an ion beam. For example, the substrate processing apparatus may be an apparatus which performs an etching process and the like on the anode current collector 200 by using an ion beam. The substrate processing apparatus may include an ion beam source IG, a process chamber RC, a substrate support SBH, a gas supply unit GS, a power supply unit PS, and a vacuum pump VP.

First, a method for manufacturing a conductive nanostructure may include preparing the anode current collector 200 in which cellulose materials are stacked. For example, cellulose nanocrystal powder may be dispersed in deionized water to prepare a solution. As an example, 0.2 g of the cellulose nanocrystal powder may be mixed with 10 ml of the deionized water to prepare a solution. Thereafter, a sheet may be coated with the solution. The solution on the sheet is dried to provide the anode current collector 200 including the stacked cellulose materials, which may function as a target TG.

The target TG may be attached onto the substrate support SBH. The gas supply unit GS may supply argon (Ar) gas, nitrogen (N) gas, and oxygen (O₂) gas to the ion beam source IG. A gas control unit MFC may be interposed between the ion beam source IG and the gas supply unit GS to control the amount of a gas supplied to the ion beam source IG. The power supply unit PS may supply power to the ion beam source IG. The ion beam source IG may be an ion gun. The ion beam source IG may convert a gas supplied from the gas supply unit GS into a plasma. Argon ions and oxygen ions may be extracted from the plasma to generate an ion beam IB. The ion beam IB may be accelerated to reach the target TG. The process chamber RC may provide a process space. The target TG may be processed in the process space. The process chamber RC may be connected to an ion beam source IG. The substrate support SBH may be located in the process chamber RC. The substrate support SBH may be connected to a substrate control unit SBC. The substrate control unit SBC may change and/or rotate an inclination angle of the substrate control unit SBH. The vacuum pump VP may be connected to the process chamber RC. By the vacuum pump VP, the process space may be maintained in a substantial vacuum state during the progress of the process.

For example, the ion beam source IG may operate under a condition of DC 3 kV/6 kW. The pressure of the ion beam source IG may be 10⁻² torr or less. The pressure of the process chamber RC may be 10⁻⁵ torr. The area of the ion beam IB may correspond to the area of the target TG. The ion fluence of the ion beam IB may be 1×10¹⁵ ions/cm²/sec to 9.602×10¹⁸ ions/cm²/sec. The above-described specific process conditions may be variously changed vary depending on the design of an experiment.

As the target TG is irradiated with the ion beam IB, cellulose materials stacked on the anode current collector 200 may be partially etched. Depending on etching conditions, the stacked cellulose materials may be partially etched to form a plurality of nanowires or a plurality of nanotubes. In addition, the size and the density of the nanowires may be controlled by controlling the irradiation time of the ion beam and the irradiation amount of the ion beam.

Metal ions may be implanted onto the target TG simultaneously with the irradiation of the ion beam IB. The implanting of the metal ions may include at least one of sputtering and ion implantation. According to some embodiments, the implanting of the metal ions may be performed, without a separate additional process, by metal ions generated when the process chamber RC collides with the ion beam IB during the ion beam IB irradiation process. The metal ions may include iron ions and/or aluminum ions.

Referring to FIG. 4 and FIG. 24, a recess RS may be formed on a side surface of a nanowire (or nanotube) NW by side etching of the side of the nanowire (or nanotube) (NW) by the ion beam (IB). The recess RS may have a depth in the first direction D1. The depth of the recess RS may increase during the ion beam IB irradiation and metal ion implantation processes.

Metal ions MT may be implanted into the recess RS. The metal ions MT may be aggregated to form the metal pattern 111 of FIG. 4. The metal ions MT may carbonize adjacent cellulose materials. The cellulose materials may be carbonized to form the carbon pattern 112 of FIG. 4, and the carbon pattern 112 may increase in height in the second direction D2. The first shell region 110 including the metal pattern 111 and the carbon pattern 112, which are alternately and repeatedly disposed in FIG. 2, may be formed by the above-described processes. A region of the nanowire NW into which the metal ions MT has not penetrated may become the core region 120. The carbon particles 122 may also be formed in the core region 120. By the carbonization process, the second shell region 130 surrounding the first shell region 110 may be formed.

In summary, the anode for a secondary battery may be formed by stacking cellulose materials on the anode current collector 200 to form a cellulose layer, irradiating an ion beam onto the cellulose layer to partially etch the cellulose materials, and allowing remaining part thereof to constitute the core region 120, and while irradiating the ion beam, implanting the metal ions MT to form the metal pattern 111 and the carbon pattern 112 alternately repeated on the core region 120. The metal pattern 111 may be formed by implanting the metal ions onto the surface of the core region 120, and the carbon pattern 112 may be formed by carbonizing the core region 120 adjacent to the metal pattern 111 while forming the metal pattern 111.

Since the first and second shell regions 110 and 130 are formed on the core region 120 by the metal ion implantation and carbonization processes, the core structure 121 may be prevented from being decomposed into cellulose nanocrystals by the electrolyte EL. That is, since the first and second shell regions 110 and 130 prevent the core structure 121 from being decomposed into the cellulose nanocrystals by the electrolyte EL, the core structure 121 may have improved mechanical strength compared to a case in which the first and second shell regions 110 and 130 are not formed. As a result, the conductive nanostructure 100 including the core structure 121 may have improved mechanical strength, the anode for a secondary battery may have improved stability, and the anode for a secondary battery may have improved lifespan characteristics.

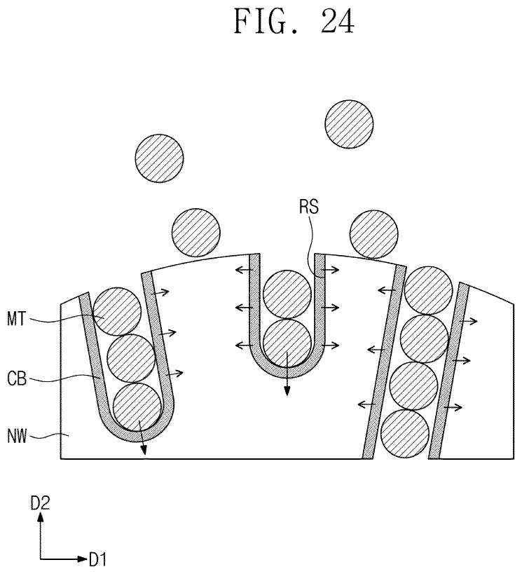

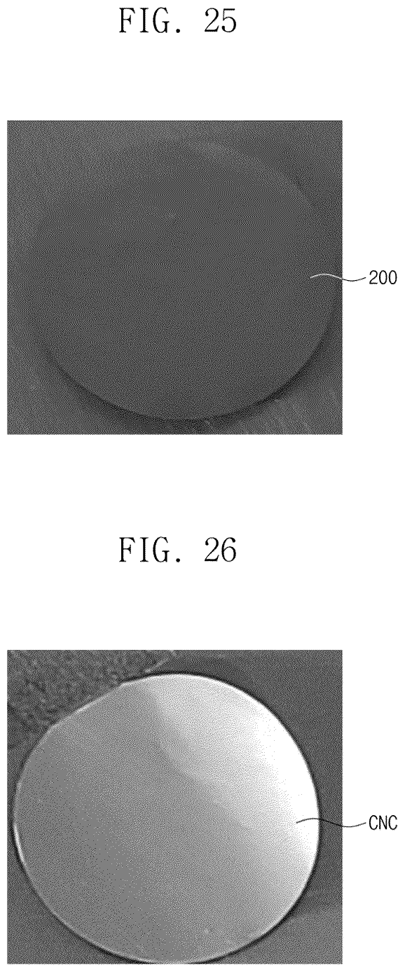

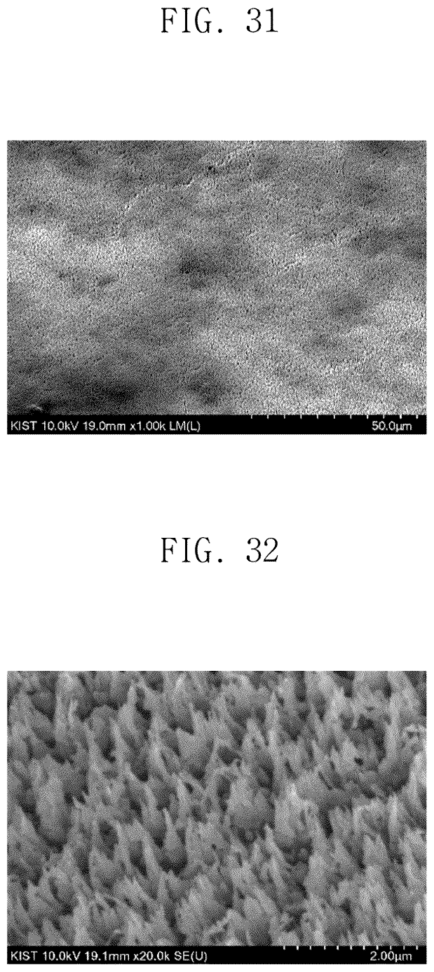

FIG. 25 to FIG. 36 are photographs showing a process of manufacturing an anode for a secondary battery according to an embodiment of the inventive concept.

Referring to FIG. 25, an anode current collector 200 may be formed of a copper (Cu) thin film.

Referring to FIG. 26, cellulose nanocrystals may be stacked on the anode current collector 200 described with reference to FIG. 25 to form a cellulose layer CNC, and the shape thereof may be observed through a photograph. The cellulose layer CNC of the present embodiment was stacked to a thickness of approximately 20 μm.

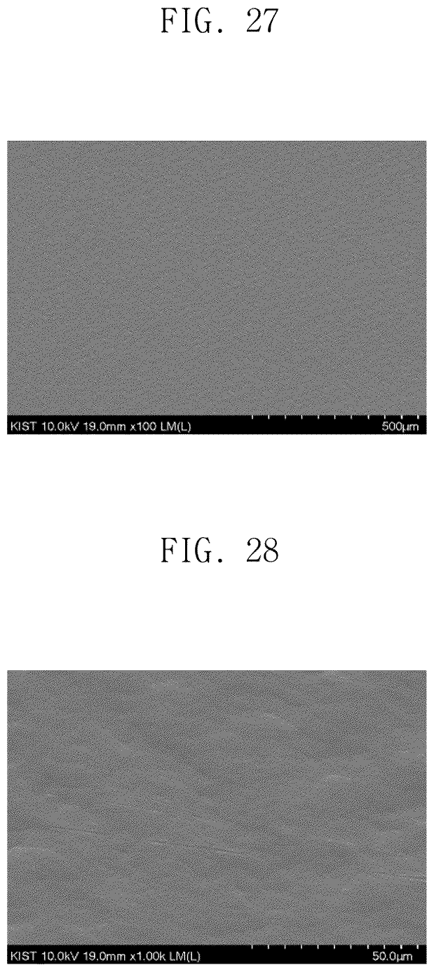

Referring to FIG. 27 and FIG. 28, the shape of the cellulose layer CNC described with reference to FIG. 26 may be observed in more detail through an SEM photograph.

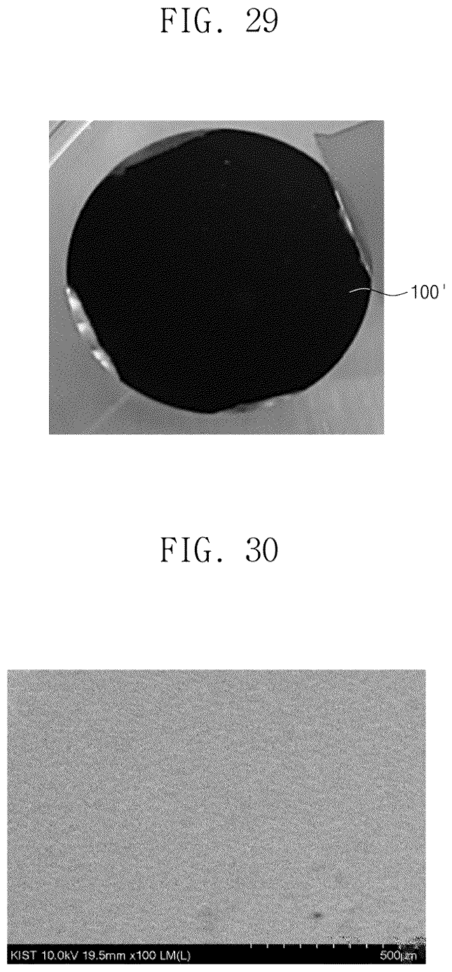

Referring to FIG. 29, a conductive nanostructure 100′may be formed by irradiating an ion beam onto the anode current collector 200 described with reference to FIG. 26 and the cellulose layer CNC on the anode current collector, and the shape thereof may be observed through a photograph. The present embodiment was manufactured by irradiating the cellulose layer CNC with an argon (Ar) ion beam having an energy of approximately 2 Kv for 30 minutes.

Referring to FIGS. 30, 31, and 32, the shape of the conductive nanostructure 100′ described with reference to FIG. 29 may be observed in more detail through an SEM photograph. It can be observed that a portion of an upper surface of the cellulose layer CNC is etched by the ion beam to form the conductive nanostructures 100′, and it can be confirmed that the conductive nanostructures 100′ have a shape of extending perpendicular to the anode current collector 200. The conductive nanostructure 100′ according to the present embodiment was measured to have a height of approximately 10 μm from the anode current collector 200.

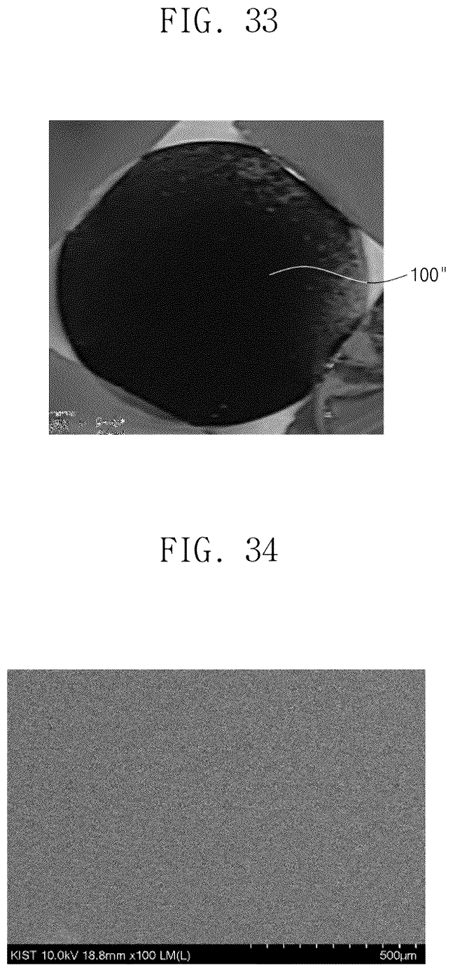

Referring to FIG. 33, the conductive nanostructure 100′ may be formed by irradiating an ion beam onto the anode current collector 200 described with reference to FIG. 26 and the cellulose layer CNC on the anode current collector, and the shape thereof may be observed through a photograph. The present embodiment was manufactured by irradiating the cellulose layer CNC with an argon (Ar) ion beam having an energy of approximately 2 Kv for 1 hour.

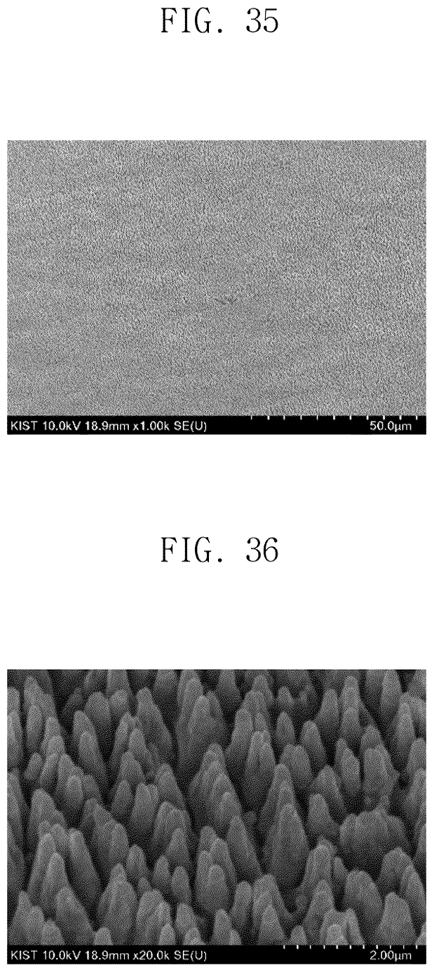

Referring to FIGS. 34, 35, and 36, the shape of the conductive nanostructure 100′ described with reference to FIG. 33 may be observed in more detail through an SEM photograph. It can be observed that a portion of an upper surface of a cellulose layer CNC is etched by an ion beam to form a conductive nanostructures 100″, and it can be confirmed that the conductive nanostructures 100″ have a shape of extending perpendicular to an anode current collector 200. The conductive nanostructure 100″ according to the present embodiment was measured to have a height of approximately 5 μm from the anode current collector 200.

In addition, comparing FIG. 32 and FIG. 36, it can be observed that as the time for irradiating the argon (Ar) ion beam increases, the height of the conductive nanostructures 100′ and 100″ decreases, and the distance between the conductive nanostructures 100′ and 100″ increases.

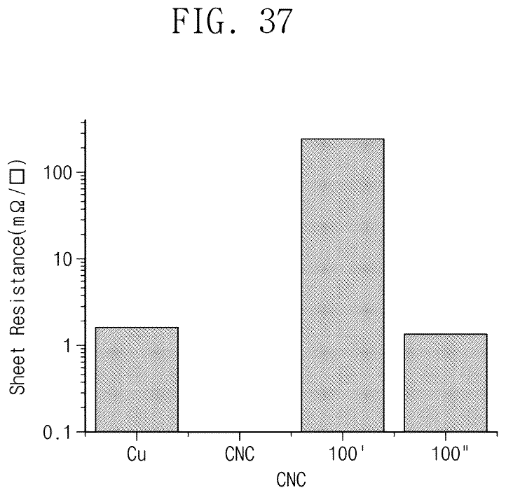

FIG. 37 shows experimental data showing sheet resistance of each of embodiments and comparative embodiments of the inventive concept. However, the sheet resistance of the cellulose layer CNC, which is an insulator, is too high and is not displayed in the graph.

Referring to FIG. 37, the sheet resistance of the copper (Cu) thin film was approximately 2 mΩ/cm², the sheet resistance of the cellulose layer CNC described with reference to FIG. 26 was 10⁸ Ω/cm², the sheet resistance of the conductive nanostructure 100′ described with reference to FIG. 29 was 200 mΩ/cm², and the sheet resistance of the conductive nanostructure 100″ described with reference to FIG. 33 was 1.5 mΩ/cm². The sheet resistances were measured using a 4-point probe.

That is, when the cellulose layer CNC described with reference to FIG. 26 is irradiated with the ion beam for about 1 hour, the sheet resistance of the conductive nanostructure 100″ may be lower than the sheet resistance of the copper (Cu) thin film, so that the electrical conductivity of an anode including the conductive nanostructure 100″ may be higher than the electrical conductivity of a copper (Cu) electrode.

An anode for a secondary battery according to the inventive concept may include an anode current collector, core regions including cellulose nanocrystals on an anode current collector, and a shell region disposed on each of the core regions. The shell region may include a metal pattern and a carbon pattern which have high electrical conductivity. Due to the shape of the core region having a large contact area with an electrolyte and the metal pattern in the shell region, the wettability between the electrolyte and the anode may be improved, so that the electrical conductivity of the anode for a secondary battery may be improved.

Although the embodiments of the present invention have been described with reference to the accompanying drawings, those skilled in the art will understand that the present invention can be implemented in other specific forms without changing the technical spirit or essential features thereof. It is therefore to be understood that the above-described embodiments are illustrative in all aspects and not restrictive.

What is claimed is:

1. An anode for a secondary battery, the anode comprising:
an anode current collector; and
a conductive nanostructure on the anode current collector, wherein the conductive nanostructure includes:
a core region including a core structure; and
a first shell region including alternately stacked metal patterns and carbon patterns, and covering the core region.

2. The anode for a secondary battery of claim 1, wherein the conductive nanostructure has a shape of at least one of a nanowire, a nanotube, and a nanopyramid.

3. The anode for a secondary battery of claim 1, wherein the conductive nanostructure further comprises a second shell region covering the first shell region.

4. The anode for a secondary battery of claim 3, wherein the second shell region is spaced apart from the core region.

5. The anode for a secondary battery of claim 3, wherein the second shell region comprises a carbon liner.

6. The anode for a secondary battery of claim 3, wherein the thickness of the second shell region is smaller than the thickness of the first shell region.

7. The anode for a secondary battery of claim 1, wherein the core structure comprises at least one of cellulose nanocrystals, cellulose nanofibers, cellulose nanoparticles, or a combination thereof.

8. The anode for a secondary battery of claim 1, wherein each of the metal patterns comprises at least one of silicon, graphene, graphite, iron, gold, silver, platinum, palladium, iridium, ruthenium, titanium, nickel, copper, zinc, tin, magnesium, aluminum, or a combination thereof.

9. The anode for a secondary battery of claim 1, wherein the anode current collector comprises at least one of iron, aluminum, titanium, copper, or a combination thereof.

10. The anode for a secondary battery of claim 1, wherein the conductive nanostructure extends in a first direction perpendicular to the anode current collector, wherein the conductive nanostructure has a height of approximately 10 nm to approximately 50 μm in the first direction.

11. The anode for a secondary battery of claim 1, wherein the conductive nanostructure has a diameter of approximately 1 nm to approximately 3 μm.

12. The anode for a secondary battery of claim 1, wherein each of the carbon patterns has a thickness of approximately 3 nm to approximately 20 nm in the first direction.

13. The anode for a secondary battery of claim 1, wherein each of the metal patterns has a thickness of approximately 3 nm to approximately 50 nm in the first direction.

14. The anode for a secondary battery of claim 1, wherein the conductive nanostructure has an aspect ratio of approximately 0.4 to approximately 700.

15. An anode for a secondary battery comprising:
an anode current collector;
a plurality of core regions extending on the anode current collector in a first direction perpendicular to the anode current collector;
first shell regions covering each of the core regions, and including metal patterns and carbon patterns alternately stacked along the first direction; and
second shell regions covering each of the first shell regions, and including a carbon liner,
wherein each of the core regions includes a core structure and carbon particles.

16. The anode for a secondary battery of claim 15, wherein the core structure comprises at least one of cellulose nanocrystals, cellulose nanofibers, cellulose nanoparticles, or a combination thereof.

17. A method for manufacturing an anode for a secondary battery, the method comprising:
forming a cellulose layer by stacking cellulose nanocrystals on an anode current collector; and
irradiating an ion beam onto the cellulose layer to form a core region, and while irradiating the ion beam, implanting metal ions onto the cellulose layer to form metal patterns and carbon patterns alternately repeated on the core region.

18. The method of claim 17, wherein the forming of the metal patterns and the carbon patterns comprises forming the metal patterns by implanting the metal ions onto the core region, and while forming the metal patterns, simultaneously forming the carbon patterns by carbonizing the core region adjacent to each of the metal patterns.

19. The method of claim 17, wherein the ion beam comprises an argon ion beam.

20. The method of claim 17, wherein the implanting of the metal ions comprises at least one of a sputtering process and an ion implantation process.
